(19) United States
(12) Patent Application Publication
(10) Pub. No.: US 2025/0192418 A1
(43) Pub. Date: Jun. 12, 2025

(54) CHIP-TO-CHIP WAVEGUIDE AND CONTACTLESS CHIP-TO-CHIP COMMUNICATION

(71) Applicant: Intel Corporation, Santa Clara, CA (US)

(72) Inventors: Tae Young YANG, Portland, OR (US); Tolga ACIKALIN, San Jose, CA (US); Issy KIPNIS, Berkeley, CA (US); Mehnaz RAHMAN, San Jose, CA (US); Georgios DOGIAMIS, Chandler, AZ (US); Bryce D. HORINE, Portland, OR (US)

(21) Appl. No.: 18/875,174

(22) PCT Filed: Jul. 28, 2022
(86) PCT No.: PCT/US2022/038612

§ 371 Date: Dec. 16, 2024

(51) Int. Cl. H01Q 1/22; H01P 5/107; H01Q 9/04; H01Q 13/20

(52) U.S. Cl. CPC H01Q 1/2283; H01P 5/107; H01Q 9/0485; H01Q 13/20

(57) ABSTRACT

A wireless chip-to-chip device includes a first semiconductor substrate comprising a first antenna, configured to emit a radiofrequency signal; a second semiconductor substrate comprising a second antenna and configured to receive the radiofrequency signal; and a waveguide, positioned between the first semiconductor substrate and the second semiconductor substrate.

### TECHNICAL FIELD

Various aspects of this disclosure generally relate to a waveguide for contactless chip-to-chip communication.

### BACKGROUND

Products developed via 3-dimensional (3D) heterogeneous chiplet integration are increasingly common, as they may provide improved performance and cost efficiency compared to monolithic integration. Such 3D heterogeneous chiplet integrations, however, conventionally rely on a wired interposer or a wired bridge to electrically-connect multiple chiplets. Although interposers permit a high interconnect density, they can be expensive and do not scale well for massive 3D integration. Furthermore, their data rates may be limited to the range of 2 Gbps to 10 Gbps. In implementations in which it is desired, for example to create an aggregate data transport of 1 Tbps or more between chiplets, the interposer requires 100 to 500 transmission lines with extremely fine pitch. This increases design complexity and expense, and it reduces yields.

Wireless chip-to-chip connections may simplify design, as they eliminate some or all of the need for chip-to-chip wire connections. Unfortunately, wireless chip-to-chip connections often result in crosstalk and interference that increases communication complexity and/or reduces data rates.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts a wireless chip-to-chip device with cross-talk interference;

FIG. 2 depicts noise power in the real domain;

FIG. 3 depicts an at least 30-dB stream-to-stream isolation in the transmit channel;

FIG. 4 depicts the wireless chip-to-chip device;

FIG. 5 depicts various exemplary configurations of the plurality of first reflectors and the plurality of second reflectors;

FIG. 6 depicts a multiport package of a chip-to-chip device;

FIG. 7 depicts a simulated electrical-field distribution of four pseudo-independent channels using a waveguide structure;

FIG. 8 depicts the structure of FIG. 7 with four simultaneous active channels;

FIG. 9 depicts an alternative configuration with multiple through-vias to build a single reflector element;

FIG. 10 depicts the chip-to-chip structure with a monolithic die and non-monolithic die;

FIG. 11 depicts a configuration with an optional electrically conductive connection between the chips;

FIG. 12 depicts a multichip stack of chip-to-chip devices;

FIG. 13 depicts an alternative configuration in which the waveguide is coupled to an integrated heat spreader; and

FIG. 14 depicts an optional configuration in which the waveguide is configured as a 1-to-2 waveguide.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPointTM, among others, or any combination thereof. Registers, shift registers, processor registers, data buffers, among others, are also embraced herein by the term memory. The term “software” refers to any type of executable instruction, including firmware.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

The term “adjacent” is intended to mean “next to” but not necessary intended to indicate “touching”. That is, two objects may be described as being “adjacent to” one another, but this should not necessary be understood to indicate that the two objects makes physical contact with one another. For example, two waveguides that are adjacent are to be understood as being next to one another but not necessary touching one another. A substrate and a waveguide that are described as being adjacent may be next to one another by have a small gap between them.

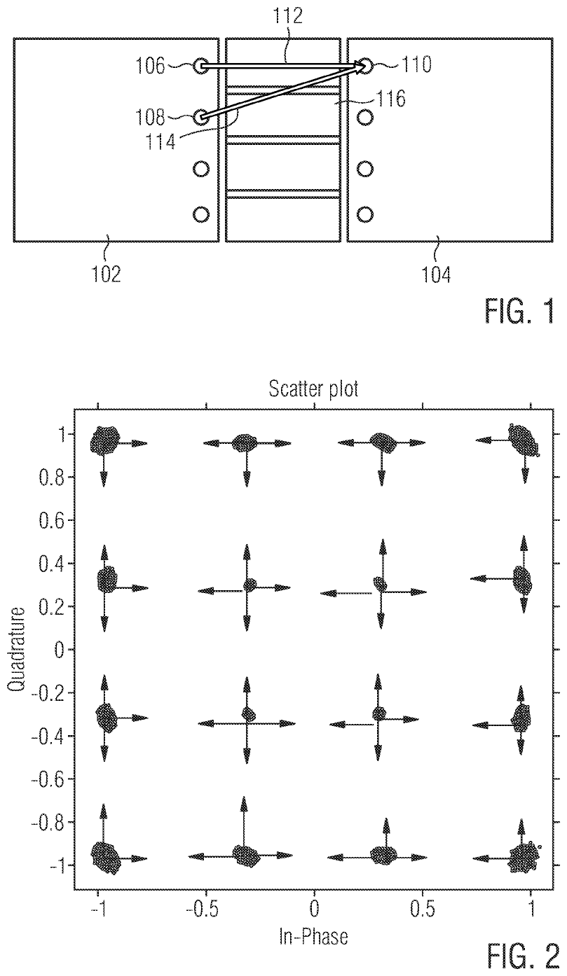

FIG. 1 depicts a wireless chip-to-chip device with cross-talk interference. In this example, a first chiplet 102 has four communication ports (port 1 is labeled as 106 and port 2 is labeled as 108). A second chiplet 104 also has 4 communication ports (port 5 is labeled as 110). The first chiplet 102 attempts to communicate from port 1 106 to port 5 110 by sending a first electromagnetic signal 112. The first chiplet 102 simultaneously sends a second electromagnetic signal 114 from port 2 108 to port 6 (not labeled, but directly below port 5 110). The second electromagnetic signal 114 travels in part through and/or around the waveguide 116, but in circumstances in which there is insufficient isolation between the waveguide 116 and adjacent waveguides, the second electromagnetic signal 114 interferes with the first electromagnetic signal 112.

Additional isolation between transport channels represents a tradeoff, as increased isolation is necessary for certain high-speed communication, but it also increases cost and design complexity. As such, it is necessary to determine a preferred isolation between channels.

Considering a gray coded 16 quadrature amplitude modulation (QAM) over an additive white Gaussian noise (AWGN) channel, the exact bit error rate (BER) is given by:

$${P}_{e} = \frac{3}{4} Q ( \sqrt{\frac{{d}_{min}^{2}}{4 {σ}_{e}^{2}}} ) + \frac{1}{2} Q ( 3 \sqrt{\frac{{d}_{min}^{2}}{4 {σ}_{e}^{2}}} ) - \frac{1}{4} Q ( 5 \sqrt{\frac{{d}_{min}^{2}}{4 {σ}_{e}^{2}}} ) \qquad ( 1 )$$

where dₘᵢₙ is the distance between two constellation points and σₑ² is the error power in the real domain. The average transmitted symbol power, Eₛ, can be written in terms of dₘᵢₙ as

$${E}_{s} = \frac{5}{2} {d}_{min}^{2} \qquad ( 2 )$$

The error vector magnitude (EVM) is then given as:

$$EVM = \frac{2 {σ}_{e}^{2}}{{E}_{s}} = \frac{4 {σ}_{e}^{2}}{5 {d}_{min}^{2}} \qquad ( 3 )$$

The bit error rate (BER) in term of EVM is found as the following:

$${P}_{e} = \frac{3}{4} Q ( \sqrt{\frac{1}{5 EVM}} ) + \frac{1}{2} Q ( 3 \sqrt{\frac{1}{5 EVM}} ) - \frac{1}{4} Q ( 5 \sqrt{\frac{1}{5 EVM}} ) \qquad ( 4 )$$

However, the example channel does not have AWGN. Rather, it also has distortions due to the interference from the cross-link. Therefore, it is necessary to calculate the real domain error power (σₑ²) with the distortions. The real noise power is denoted with distortion as σ_{d}². The EVM with distortion can thus be shown as:

$${EVM}_{d} = \frac{4 {σ}_{d}^{2}}{5 {d}_{min}^{2}} \qquad ( 5 )$$

FIG. 2 depicts noise power at all constellations in the real domain (depicted by arrows). The maximum power is selected, and the BER and the EVM are calculated with distortions. It is noteworthy that the dominant error here comes from corner points. There is also some maximization bias due to the worst distortion case scenario. Thus, once can consider that a 4×10⁻¹² BER with the bias is equivalent to a 10⁻¹² BER, which corresponds to −23.8 dB EVM_{d}.

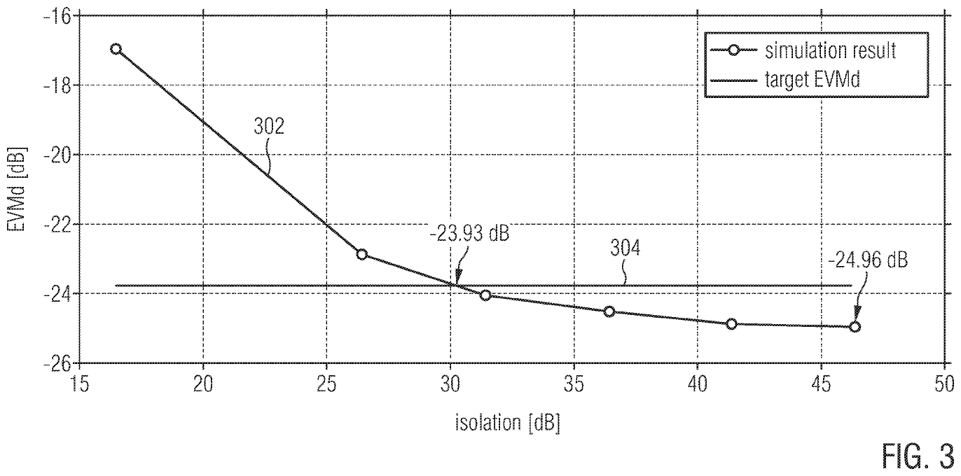

By varying the isolation level difference between the direct and cross channels, one may observe that an at least 30-dB stream-to-stream isolation achieves a target −23.8 dB EVM_{d}, as depicted in FIG. 3. Thus, a single channel with −23.8 dB EVM_{d} can achieve 186.7 Gb/s with 16QAM modulation with no additional framing and coding overhead. Accordingly, channels with more than 30-dB stream-to-stream isolation can be treated as pseudo-independent channels, and the throughputs of these channels can be aggregated. For example, an array of seven contactless waveguides would be needed to support 1+Tbps aggregated throughputs within the 110-170 GHz frequency range.

Beyond the channel isolation, it is necessary to select a suitable antenna configuration for data transmission. Vertically-polarized couplers may permit improved operational bandwidth and greater efficiency as compared to horizontally-polarized couplers; however, fitting a vertically-polarized coupler into the die presents significant challenges, considering that a metal layer is typically less than 20 μm thick. Given the sub-THz coupler height versus performance trade-offs, the theoretical minimum height of the sub-THz coupler is approximately 100 μm, but it would actually need to be taller than 100 μm in practice because typical coupler design performance (patch, PIFA, dipole couplers) may be significantly less than the theoretical limit curve. In addition, extra loss from materials in proximity to coupler must be considered.

Given this vertically-polarized coupler height requirement (>100 μm), implementation of the antenna within the substrate may be desirable. The coupler may be implemented inside the substrate using through-substrate antennas to meet the maximum channel loss requirement. According to an aspect of the disclosure, the through-substrate antennas may be configured as through-vias (e.g. through-silicon-vias).

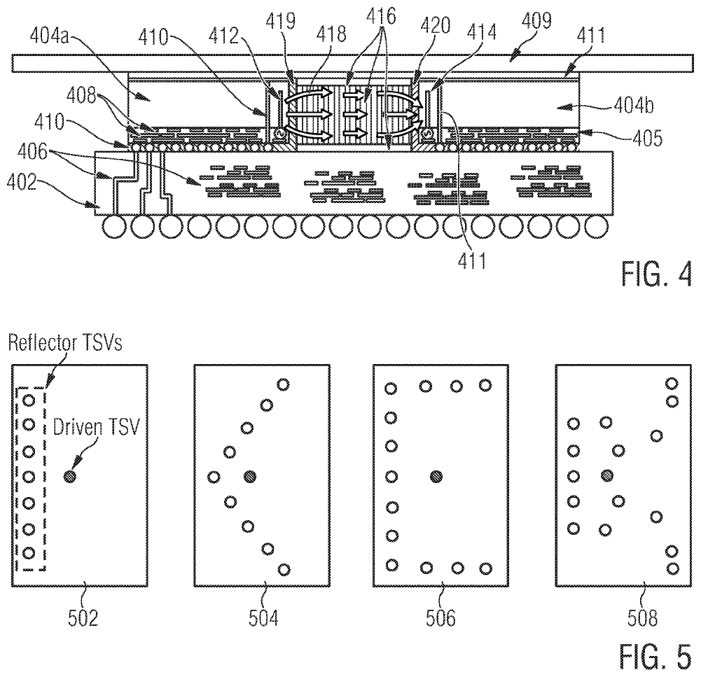

FIG. 4 depicts the wireless chip-to-chip device with substrate-implemented antennas and waveguide, according to an aspect of the disclosure. The wireless chip-to-chip device may include a package substrate 402. The wireless chip-to-chip device includes a first substrate 404a and a second substrate 404b. Each of the first substrate 404a and the second substrate 404b may be made of or include silicon, metal oxide, glass, Three Five (III-V) materials (GaN, InP, GaAs), or any combination thereof.

The first substrate 404a may include a first antenna 412, configured to emit a radiofrequency signal; the second substrate 404b may include a second antenna 414, which may be configured to receive the radiofrequency signal.

The wireless chip-to-chip device may further include a waveguide 416, positioned between the first silicon substrate 404a and the second silicon substrate 404b. That is, the waveguide may be located in-between dies with a small gap between the edge of the die and the edge of the waveguide (typically <150 μm or less than bump pitch). The waveguide may optionally be loaded with a material (relative permittivity εr≥1 and/or relative permeability μr≥1). The waveguide may alternatively be hollow, such as in which the waveguide is filled with air (e.g. an air dielectric). The small gap between the respective die and the waveguide may be an empty or hollow gap (e.g. filled with air) or be filled with an underfill material. This underfill material may optionally be or include one or more magneto-dielectric materials. For the purposes of this disclosure, a magneto-dielectric material may be understood as a material with both a relative permeability and a permittivity>1, whereas a dielectric material exhibits a permittivity>1 and relative permeability=1. An air dielectric exhibits both a relative permittivity and permeability of 1.

In one configuration, the waveguide 416 may be configured to be excited with the fundamental TE mode as a dominant mode. As such, the cut-off frequency is mainly limited by the waveguide's width, rather than its height, which may be advantageous. The dielectric material may be selected to load the waveguide, but the material discontinuity can increase the difficulty in wideband operation. This may be particularly true when the gap is not filled with an underfill material that is matched to the waveguide loading material. Thus, magneto-dielectric materials (relative permittivity εᵣ=relative permeability μᵣ) may be used to mitigate the discontinuity issues and minimize the size of the waveguide.

The array of waveguides may be formed in a horizontal (xy; side-to-side placement) and/or a vertical (z: top-to-bottom placement; stacked placement) plane to increase the aggregated throughputs, such that stream-to-stream isolation between the waveguides is at least 30 dB. These high-isolation waveguides form pseudo-independent channels, which reduces cross-talk/interference and improves BER.

According to an aspect of the disclosure, the waveguide structures may be fabricated using multi-layered low temperature co-fired ceramics (LTCC) or high temperature co-fired ceramics (HTCC). Alternatively, the waveguides may be formed by selective metallization of various substrates (e.g. quartz, glass, etc.). The waveguide loading material may be the same as that of the main substrate, or it can be made hollow and filled by another dissimilar material.

The wireless chip-to-chip device may optionally further include a first magneto-dielectric material 419 between the first silicon substrate 404a and the waveguide 416 and/or a second magneto-dielectric material 420 between the second silicon substrate 404b and the waveguide 416. The wireless chip-to-chip device may be configured to propagate a wireless signal 418 from the first antenna 412, through the waveguide 416, to the second antenna 414.

According to an aspect of the disclosure, the first antenna 412 and the second antenna 414 may be polarized along an axis that is perpendicular to an axis through the first silicon substrate 404a, the waveguide 416, and the second silicon substrate 404b. That is, the first antenna 412 and the second antenna 414 may be vertically polarized.

In an exemplary configuration, the first antenna 412 and the second antenna 414 may be parallel to each other. That is, they may be arranged to have an identical polarization, so as to improve transmission and reception of the corresponding electromagnetic signal.

According to an aspect of the disclosure, an exterior portion of the waveguide 416 may include a metallic layer. In one exemplary configuration, the metal may be copper. The metal is, however, not limited to copper and may be any metal. Addition of the metal layer may further electromagnetically insulate the waveguide from adjacent waveguides and thus prevent or reduce crosstalk or interference.

According to an aspect of the disclosure, an interior portion of the waveguide may include a dielectric material. In an exemplary configuration, the dielectric material may be air. Alternatively, other dielectric materials may be used. A non-exhaustive list of such potential dielectric materials includes glass, lithium niobate (LiNb03), indium gallium arsenide phosphide/indium phosphide (InGaAsP/InP), aluminum gallium arsenide/gallium arsenide (AlGaAs/GaAs), and silica.

According to an aspect of the disclosure, the first silicon substrate 404a may further include a plurality of first reflectors 410; wherein at least one of the plurality of first reflectors is positioned opposite the waveguide 416 relative to the first antenna 412. That is, the first antenna 412 is positioned between at least one (e.g. potentially more than one, or potentially all) first reflector 410. In an exemplary configuration, the plurality of first reflectors 410 may be a plurality of vias (e.g. metallic vias, through silicon vias, through substrate vias, etc.).

Similarly, the second silicon substrate 404b may further include a plurality of second reflectors 411; wherein at least one of the plurality of second reflectors is positioned opposite the waveguide 416 relative to the second antenna 414. That is, the second antenna 414 is positioned between at least one (e.g. potentially more than one, or potentially all) second reflector 411. In an exemplary configuration, the plurality of second reflectors 411 may be a plurality of vias (e.g. metallic vias, through silicon vias, through substrate vias, etc.).

Various arrangements of the plurality of first reflectors and the plurality of second reflectors are possible. Principally, an arrangement of the plurality of first reflectors in the plurality of second reflectors may be chosen to reflect a radiofrequency signal from the first antenna toward the waveguide and/or to reflect the radiofrequency signal from the waveguide to the second antenna.

FIG. 5 depicts various exemplary configurations of the plurality of first reflectors 410 and the plurality of second reflectors 411. In a first exemplary configuration, each of the plurality of first reflectors 410 and the plurality of second reflectors 411 may be arranged along an axis perpendicular to a longitudinal axis of the waveguide as depicted in 502. In a second exemplary configuration, the plurality of first reflectors includes a first subgroup of first reflectors and a second subgroup of first reflectors; wherein the first subgroup of first reflectors is arranged along a first axis; wherein the second subgroup of first reflectors is arranged along a second axis; and wherein each of the first axis and the second axis are at an angle of fewer than 90 degrees relative to a longitudinal axis of the waveguide as depicted in 504. In the third exemplary configuration, the plurality of first reflectors includes a first subgroup of first reflectors, a second subgroup of first reflectors, and a third subgroup of first reflectors; wherein the first subgroup of first reflectors is arranged along a first axis perpendicular to a longitudinal axis of the waveguide; and wherein the second subgroup of first reflectors and the third subgroup of first reflectors are each arranged along axes parallel to the longitudinal axis of the waveguide as depicted in 506. In a fourth exemplary configuration, the plurality of first reflectors includes a first subgroup of first reflectors, a second subgroup of first reflectors, and a third subgroup of first reflectors; wherein the first subgroup of first reflectors is arranged along a first axis perpendicular to a longitudinal axis of the waveguide; and wherein each of the second subgroup of first reflectors and the third subgroup of first reflectors are arranged along a curve, such that a distance between a reflector of the second subgroup of first reflectors or the third subgroup of first reflectors and a longitudinal axis of the waveguide increases as a distance between the reflector and the waveguide decreases as depicted in 508. The above-listed exemplary configurations of reflectors are intended as a non-exhaustive list, and other arrangements may be selected for a given implementation. Otherwise stated, a non-exhaustive list of the potential shapes includes a “flat” shape 502, a rotated-“V” shape 504, a rotated-“U” shape 506, or other polygonal shapes (e.g. as in 508). The polygonal shape in 508 represents an optional shape in which the reflector and pitches between the reflector through-vias have been optimized to broaden the operational bandwidth and isolation between adjacent couplers. Other shapes that are not depicted herein may be used. The skilled person may arrive at alternative shapes using one or more optimization algorithms, such as a genetic algorithm, particle swarm optimization, Covariance Matrix Adaptation Evolution Strategy (CMA ES), or otherwise.

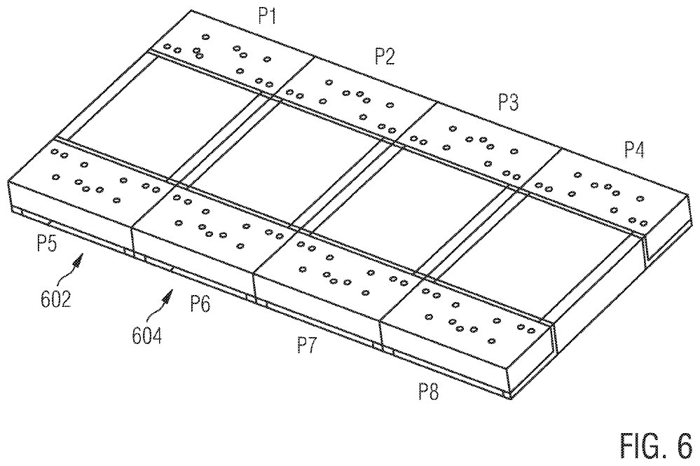

FIG. 6 depicts a multiport package of a chip-to-chip device according to an aspect of the disclosure. In this multipoint package, a wireless chip-to-chip device is depicted as having a first chip with ports P1, P2, P3, and P4, and a second chip with ports P5, P6, P7, and P8. Four pseudo-isolated channels are created using the waveguide structure as disclosed herein, such that each of a first channel between P1 and P5, a second channel between P2 and P6, the third channel between P3 and P7, and a fourth channel between P4 and P8 is isolated (e.g., pseudo-isolated, has at least 30 dB of isolation) from its adjacent channels.

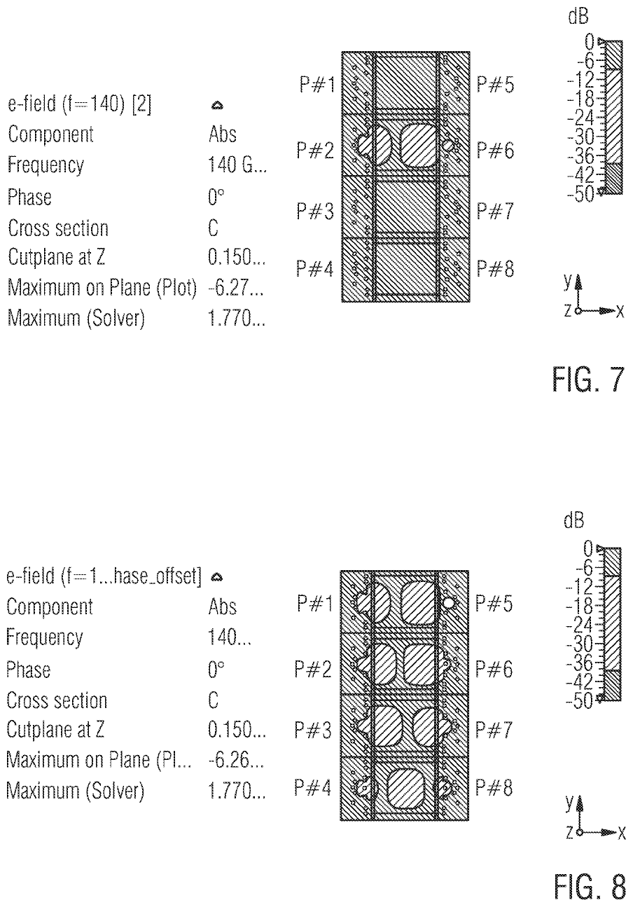

FIG. 7 depicts a simulated electrical-field distribution of four pseudo-independent channels using a waveguide structure as disclosed herein. In FIG. 7, only channel two (e.g. including P2 and P6) is activated. It can be seen that the channel has greater than 30 dB of isolation from its adjacent channels. FIG. 8 depicts the same structure, but in which each of channels 1 (P1 and P5), 2 (P2 and P6), 3 (P3 and P7) and 4 (P4 and P8) is activated. Once can see that the adjacent channels are isolated from one another and are essentially free of cross-talk/interference from adjacent channels. In a simulation of the 4-channel waveguide model according to FIG. 8, when operated within the 110-170 GHz frequency range, and wherein the waveguide is filled with an underfill material (εᵣ=3.38 and tanδ=0.016 at 140 GHz) the conductivity of the silicon substrate is assumed to be 10 S/m, and the reflection coefficient at the coupler excitation port is less than −10 dB for the entire D band (110-170 GHz). The direct link signal level between dies with 1-mm separation distance is about −8 dB on average. The stream-to-stream isolation (amplitude difference between direct link and cross links) is higher than 40 dB.

The interference between adjacent waveguide channels is sufficiently low that the waveguide structure as disclosed herein essentially creates pseudo-independent channels, as demonstrated through electric-field-distribution simulations in FIG. 8. The data throughputs of these channels can be seamlessly aggregated, and the number of pseudo-independent channels is scalable in all 3-dimensional directions, i.e. x, y, and z directions, for heterogeneous chiplet integration.

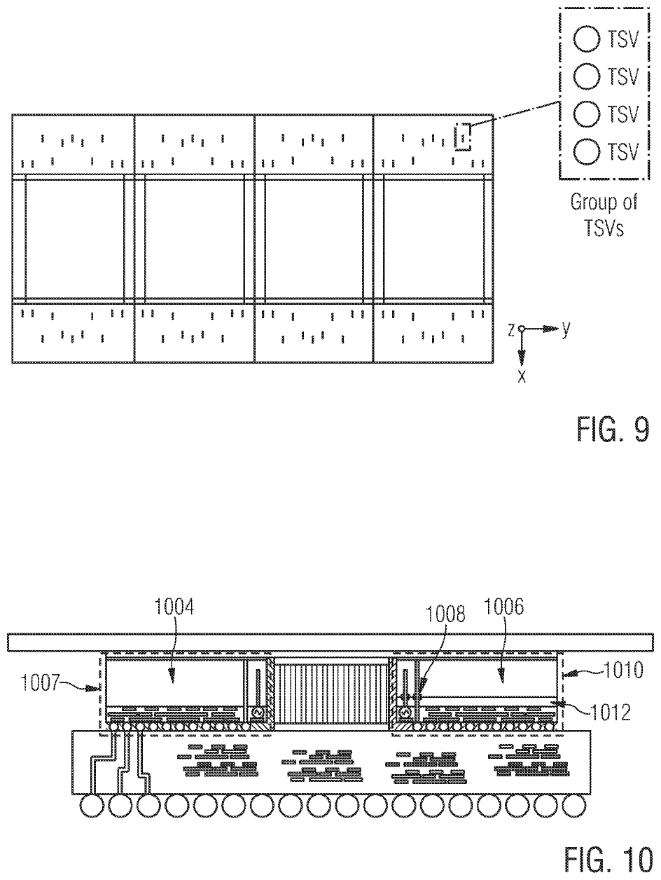

FIG. 9 depicts an alternative configuration using multiple through-vias to build a single reflector element. In this figure, each of the first substrate and the second substrate includes a plurality of reflectors as disclosed above. In this exemplary configuration, the reflectors are/include the through-vias (e.g. through silicon vias). One portion of the reflector structure is arbitrarily selected, and an exploded view of this reflector structure is indicated by the arrow. It can be seen that this reflector structure includes a plurality of through-vias, which are placed in sufficiently close proximity to effectively create a single structure. As technology exists to place vias within a substrate at a high degree of accuracy, it may be desirable in certain implementations to group a plurality of through-vias in close proximity so as to create a reflector structure. Of note, although this technique is described herein with respect to through-vias, it may alternatively be used with any other metal structure, such as a wire, post, metal trace, or otherwise.

FIG. 10 depicts the chip-to-chip structure as described above with a monolithic die and non-monolithic die. In this figure, the chip-to-chip device includes a first silicon substrate 1004 as part of a monolithic die as described above. In place of the second substrate as described above, the chip-to-chip device may include two or more layers as shown by 1010 and 1012. In this case, 1010 may be a silicon, glass, or organic substrate, and 1012 may be a silicon substrate. Each of 1010 and 1012 may include an antenna (e.g. a through-via, etc.). These antennas may be joined at the interface of 1010 and 1012 with a bond 1008. The bond 1008 may be or include hybrid bonding, direct bonding, or any other bonding method.

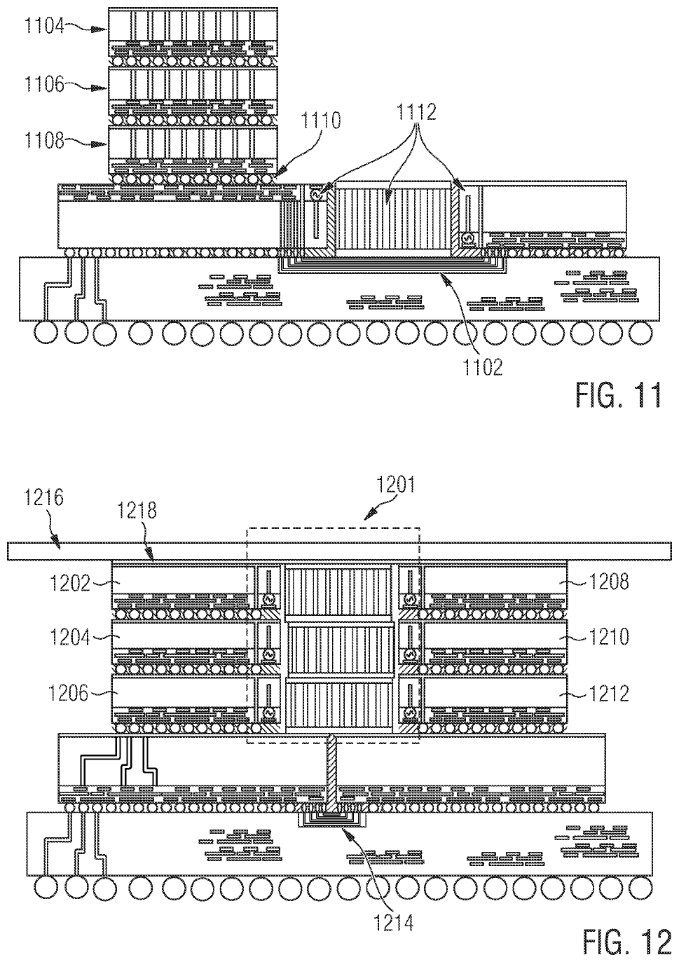

FIG. 11 depicts a configuration with an optional electrically conductive connection between the chips. In this configuration, the contactless chip-to-chip device as described herein may be supplemented or augmented with a wired connection 1102, such as, for example, an embedded multi-die interconnect bridge. In certain configurations, one or more chips on one side of the chip-to-chip device (for example the chip on the right side of the waveguide in FIG. 11) may be able to connect to one or more chips via a waveguide as disclosed herein, but also require connection to one or more additional chips for which a waveguide connection is impracticable or undesirable. In this exemplary configuration, the multichip structure includes a first DRAM die 1104, a second DRAM die 1106, and a compute die 1108. Each of 1104, 1106, and 1108, are connected to a wired interconnect 1102, such as through face-to-face microbumps 1110. In this configuration, each of 1104, 1106, and 1108 may send and/or receive signals to other chips (e.g. the chip depicted on the right side of the waveguide) via the wired interconnect 1102 in addition to the contactless chip-to-chip communication otherwise described (e.g. on the left side and the right side of the waveguide).

FIG. 12 depicts a multichip stack of chip-to-chip devices connected with a plurality of waveguides and optional couplers (the waveguides and optional couplers being depicted as 1201) according to an aspect of the disclosure. In this example, the multichip stack includes two vertical columns of chips. The number of chips in each column is three for demonstrative purposes, but any number of chips in a stack is conceivable. Three contactless communication channels exist according to the principles and methods disclosed here, such that 1206 and 1212 share an isolated, contactless channel through a first waveguide; 1204 and 1210 share an isolated, contactless channel through a second waveguide; and 1202 and 1208 share an isolated, contactless channel through a third waveguide. The chips are additionally, optionally connected though a wired interconnect 1214 as is disclosed in FIG. 11. The chips may optionally include an integrated heat spreader 1216, which may optionally be connected to the chip stacks via a thermal interface material 1218.

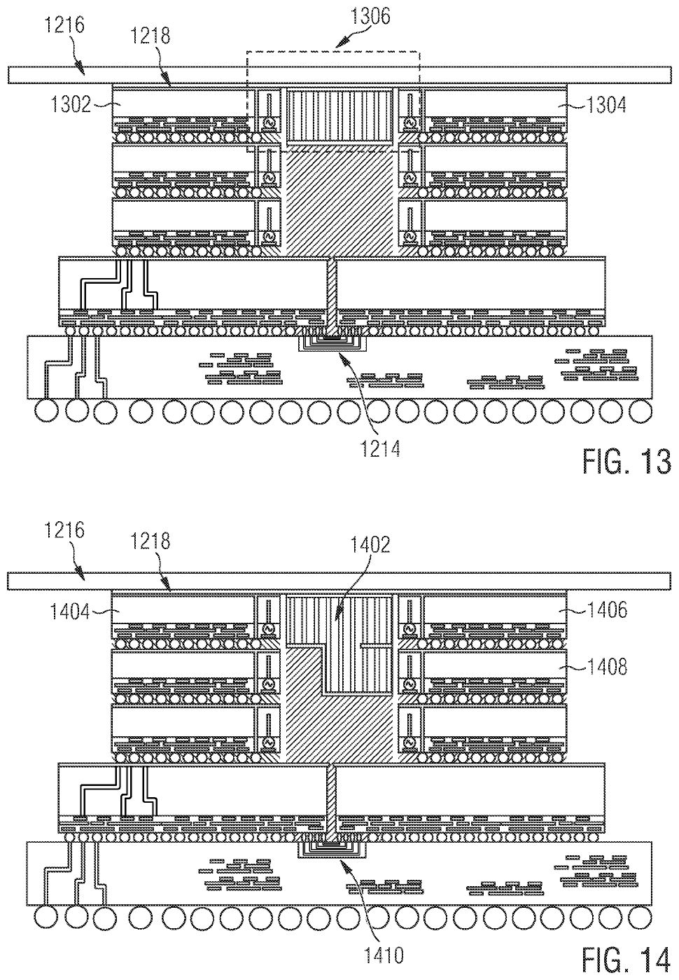

It is, of course, not necessary that the waveguide be placed on the package substrate, but instead can be placed along or against one or more other package surfaces. For example, FIG. 13 depicts an alternative configuration in which the waveguide is coupled to an integrated heat spreader. In this manner, chips 1302 and 1304 share an isolated, contactless channel via a waveguide 1306 that is connected to the integrated heat spreader 1216, such as optionally via a thermal interface material 1218.

FIG. 14 depicts an optional configuration in which the waveguide is configured as a 1-to-2 waveguide. In this configuration, the 1-to-2 waveguide 1402 connects chip 1404 on the left with chips 1406 and 1408 on the right. In this manner, a transmission from 1404 may be received by 1406 and 1408. Conversely, a transmission by either of 1408 or 1406 is received by 1404. In such a design, it may be desired to include one or more communication protocols to establish the intended recipient of a communication. For example, an identifier of the intended chip-recipient may be included in a package header. As with other configurations, some or all of the chips may be additionally be connected via a wired interconnect 1410. The 1-to-2 waveguide configuration may include third silicon substrate above or below the second silicon substrate and a third magneto-dielectric material adjacent to the third silicon substrate; and wherein the waveguide has a first opening adjacent to the first magneto-dielectric material, a second opening adjacent to the second magneto-dielectric material, and a third opening adjacent to the third magneto-dielectric material. Further stating, the 1-to-2 waveguide concept may be expanded to reflect an n-to-m waveguide concept, in which n and m are integers and n rm. In this manner, a 1-to-3, a 1-to-4, a 1-to-5 etc. waveguide may be implemented. Similarly, any of the above waveguide configurations may be reversed, such that the 1-to-2 waveguide becomes a 2-to-1 waveguide, and so forth.

Further aspects of the disclosure will now be demonstrated by way of Example.

In Example 1, a wireless chip-to-chip device includes a first silicon substrate including a first antenna, configured to emit a radiofrequency signal; a second silicon substrate including a second antenna and configured to receive the radiofrequency signal; a waveguide, positioned between the first silicon substrate and the second silicon substrate.

In Example 2, the wireless chip-to-chip device of Example 1 further includes a first magneto-dielectric material between the first silicon substrate and the waveguide; and a second magneto-dielectric material between the second silicon substrate and the waveguide.

In Example 3, the wireless chip-to-chip device of Example 1 or 2, wherein the first antenna and the second antenna are polarized along an axis that is perpendicular to an axis through the first silicon substrate, the waveguide, and the second silicon substrate.

In Example 4, the wireless chip-to-chip device of any one of Examples 1 to 3, wherein an exterior portion of the waveguide includes a metallic layer.

In Example 5, the wireless chip-to-chip device of any one of Examples 1 to 4, wherein an interior portion of the waveguide includes a dielectric material.

In Example 6, the wireless chip-to-chip device of any one of Examples 1 to 5, wherein the first silicon substrate further includes a plurality of first reflectors; wherein at least one of the plurality of first reflectors is positioned opposite the waveguide relative to the first antenna.

In Example 7, the wireless chip-to-chip device of Example 6, wherein the plurality of first reflectors is a plurality of vias.

In Example 8, the wireless chip-to-chip device of Example 6 or 7, wherein the plurality of first reflectors is arranged to reflect a radiofrequency signal of the first antenna toward the waveguide.

In Example 9, the wireless chip-to-chip device of any one of Examples 1 to 8, wherein the second silicon substrate further includes a plurality of second reflectors; wherein at least one of the second reflectors is positioned opposite the waveguide relative to the second antenna.

In Example 10, the wireless chip-to-chip device of Example 9, wherein the plurality of second reflectors is a plurality of vias.

In Example 11, the wireless chip-to-chip device of Example 9 or 10, wherein the plurality of second reflectors is arranged to reflect a radiofrequency signal of the second antenna toward the waveguide.

In Example 12, the wireless chip-to-chip device of any one of Examples 1 to 11, wherein the first antenna and the second antenna are parallel to each other.

In Example 13, the wireless chip-to-chip device of any one of Examples 6 to 12, wherein each of the plurality of first reflectors and the plurality of second reflectors is arranged along an axis perpendicular to a longitudinal axis of the waveguide.

In Example 14, the wireless chip-to-chip device of any one of Examples 6 to 12, wherein the plurality of first reflectors includes a first subgroup of first reflectors and a second subgroup of first reflectors; wherein the first subgroup of first reflectors is arranged along a first axis; wherein the second subgroup of first reflectors is arranged along a second axis; and wherein each of the first axis and the second axis are at an angle of fewer than 90 degrees relative to a longitudinal axis of the waveguide.

In Example 15, the wireless chip-to-chip device of any one of Examples 6 to 12, wherein the plurality of first reflectors includes a first subgroup of first reflectors, a second subgroup of first reflectors, and a third subgroup of first reflectors; wherein the first subgroup of first reflectors is arranged along a first axis perpendicular to a longitudinal axis of the waveguide; and wherein the second subgroup of first reflectors and the third subgroup of first reflectors are each arranged along axes parallel to the longitudinal axis of the waveguide.

In Example 16, the wireless chip-to-chip device of any one of Examples 6 to 12, wherein the plurality of first reflectors includes a first subgroup of first reflectors, a second subgroup of first reflectors, and a third subgroup of first reflectors; wherein the first subgroup of first reflectors is arranged along a first axis perpendicular to a longitudinal axis of the waveguide; and wherein each of the second subgroup of first reflectors and the third subgroup of first reflectors are arranged along a curve, such that a distance between a reflector of the second subgroup of first reflectors or the third subgroup of first reflectors and a longitudinal axis of the waveguide increases as a distance between the reflector and the waveguide decreases.

In Example 17, the wireless chip-to-chip device of any one of Examples 1 to 16 further includes a third silicon substrate above or below the second silicon substrate and a third magneto-dielectric material adjacent to the third silicon substrate; and wherein the waveguide has a first opening adjacent to the first magneto-dielectric material, a second opening adjacent to the second magneto-dielectric material, and a third opening adjacent to the third magneto-dielectric material.

In Example 18, the wireless chip-to-chip device of any one of Examples 1 to 17 further includes one or more electrically conductive connections between the first silicon substrate and the second silicon substrate.

In Example 19, the wireless chip-to-chip device of any one of Examples 1 to 18 further includes a metal layer on the waveguide.

In Example 20, the wireless chip-to-chip device of any one of Examples 1 to 19 further includes a groove on an exterior surface of the waveguide.

In Example 21, a multichip package includes a first wireless chip-to-chip device according to any one of Examples 1 to 20, and a second wireless chip-to-chip device according to any one of Examples 1 to 20.

In Example 22, the multichip package of Example 21 further includes a substrate, wherein the first wireless chip-to-chip device and the second wireless chip-to-chip device are each mounted on the substrate.

In Example 23, the multichip package of Example 21 or 22, wherein the first wireless chip-to-device includes a first material, and wherein the second wireless chip-to-device includes a second material, different from the first material.

In Example 24, the multichip package of any one of Examples 21 to 23, wherein the first wireless chip-to-device includes a first material between the first silicon substrate and the waveguide or between the second silicon substrate and the waveguide, wherein the second wireless chip-to-device includes a first material between the first silicon substrate and the waveguide or between the second silicon substrate and the waveguide; wherein the first material and the second material are different.

In Example 25, a wireless chip-to-chip device includes a first silicon substrate including a first transmission means for emitting a radiofrequency signal; a second silicon substrate including a reception means for receiving the radiofrequency signal; a wave guiding means for guiding an electromagnetic signal from the first transmission means to the second transmission means.

In Example 26, the wireless chip-to-chip device of Example 25 further includes a first magneto-dielectric material between the first silicon substrate and the wave guiding means; and a second magneto-dielectric material between the second silicon substrate and the wave guiding means.

In Example 27, the wireless chip-to-chip device of Example 25 or 26, wherein the transmission means and the reception means are polarized along an axis that is perpendicular to an axis through the first silicon substrate, the wave guiding means, and the second silicon substrate.

In Example 28, the wireless chip-to-chip device of any one of Examples 25 to 27, wherein an exterior portion of the wave guiding means includes a metallic layer.

In Example 29, the wireless chip-to-chip device of any one of Examples 25 to 28, wherein an interior portion of the wave guiding means includes a dielectric material.

In Example 30, the wireless chip-to-chip device of any one of Examples 25 to 29, wherein the first silicon substrate further includes a plurality of first signal reflection means; wherein at least one of the plurality of first signal reflection means is positioned opposite the wave guiding means relative to the transmission means.

In Example 31, the wireless chip-to-chip device of Example 30, wherein the plurality of first signal reflection means is a plurality of vias.

In Example 32, the wireless chip-to-chip device of Example 30 or 31, wherein the plurality of first signal reflection means is arranged to reflect a radiofrequency signal of the transmission means toward the wave guiding means.

In Example 33, the wireless chip-to-chip device of any one of Examples 25 to 32, wherein the second silicon substrate further includes a plurality of second signal reflection means; wherein at least one of the second signal reflection means is positioned opposite the wave guiding means relative to the reception means.

In Example 34, the wireless chip-to-chip device of Example 33, wherein the plurality of second signal reflection means is a plurality of vias.

In Example 35, the wireless chip-to-chip device of Example 33 or 34, wherein the plurality of second signal reflection means is arranged to reflect a radiofrequency signal of the reception means toward the wave guiding means.

In Example 36, the wireless chip-to-chip device of any one of Examples 25 to 35, wherein the transmission means and the reception means are parallel to each other.

In Example 37, the wireless chip-to-chip device of any one of Examples 30 to 36, wherein each of the plurality of first signal reflection means and the plurality of second signal reflection means is arranged along an axis perpendicular to a longitudinal axis of the wave guiding means.

In Example 38, the wireless chip-to-chip device of any one of Examples 30 to 36, wherein the plurality of first signal reflection means includes a first subgroup of first signal reflection means and a second subgroup of first signal reflection means; wherein the first subgroup of first signal reflection means is arranged along a first axis; wherein the second subgroup of first signal reflection means is arranged along a second axis; and wherein each of the first axis and the second axis are at an angle of fewer than 90 degrees relative to a longitudinal axis of the wave guiding means.

In Example 39, the wireless chip-to-chip device of any one of Examples 30 to 36, wherein the plurality of first signal reflection means includes a first subgroup of first signal reflection means, a second subgroup of first signal reflection means, and a third subgroup of first signal reflection means; wherein the first subgroup of first signal reflection means is arranged along a first axis perpendicular to a longitudinal axis of the wave guiding means; and wherein the second subgroup of first signal reflection means and the third subgroup of first signal reflection means are each arranged along axes parallel to the longitudinal axis of the wave guiding means.

In Example 40, the wireless chip-to-chip device of any one of Examples 30 to 36, wherein the plurality of first signal reflection means includes a first subgroup of first signal reflection means, a second subgroup of first signal reflection means, and a third subgroup of first signal reflection means; wherein the first subgroup of first signal reflection means is arranged along a first axis perpendicular to a longitudinal axis of the wave guiding means; and wherein each of the second subgroup of first signal reflection means and the third subgroup of first signal reflection means are arranged along a curve, such that a distance between a reflector of the second subgroup of first signal reflection means or the third subgroup of first signal reflection means and a longitudinal axis of the wave guiding means increases as a distance between the reflector and the wave guiding means decreases.

In Example 41, the wireless chip-to-chip device of any one of Examples 25 to 40 further includes a third silicon substrate above or below the second silicon substrate and a third magneto-dielectric material adjacent to the third silicon substrate; and wherein the wave guiding means has a first opening adjacent to the first magneto-dielectric material, a second opening adjacent to the second magneto-dielectric material, and a third opening adjacent to the third magneto-dielectric material.

In Example 42, the wireless chip-to-chip device of any one of Examples 25 to 41 further includes one or more electrically conductive connections between the first silicon substrate and the second silicon substrate.

In Example 43, the wireless chip-to-chip device of any one of Examples 25 to 42 further includes a metal layer on the wave guiding means.

In Example 44, the wireless chip-to-chip device of any one of Examples 25 to 43 further includes a groove on an exterior surface of the wave guiding means.

In Example 45, a multichip package includes a first wireless chip-to-chip device according to any one of Examples 1 to 44, and a second wireless chip-to-chip device according to any one of Examples 1 to 44.

In Example 46, the multichip package of Example 45 further includes a substrate, wherein the first wireless chip-to-chip device and the second wireless chip-to-chip device are each mounted on the substrate.

In Example 47, the multichip package of Example 45 or 46, wherein the first wireless chip-to-device includes a first material, and wherein the second wireless chip-to-device includes a second material, different from the first material.

In Example 48, the multichip package of any one of Examples 45 to 47, wherein the first wireless chip-to-device includes a first material between the first silicon substrate and the wave guiding means or between the second silicon substrate and the wave guiding means, wherein the second wireless chip-to-device includes a first material between the first silicon substrate and the wave guiding means or between the second silicon substrate and the wave guiding means; wherein the first material and the second material are different.

In Example 49, a method of manufacturing a wireless chip-to-chip device, including arranging a first antenna in a first silicon substrate, wherein the first antennas is configured to emit a radiofrequency signal; arranging a second antenna in a second silicon substrate, wherein the second antenna is configured to receive the radiofrequency signal; and arranging a waveguide between the first silicon substrate and the second silicon substrate.

In Example 50, the method of claim 49, further including arranging a first magneto-dielectric material between the first silicon substrate and the waveguide; and arranging a second magneto-dielectric material between the second silicon substrate and the waveguide.

In Example 51, the method of claim 49 or 50, wherein the first antenna and the second antenna are polarized along an axis that is perpendicular to an axis through the first silicon substrate, the waveguide, and the second silicon substrate.

In Example 52, the method of any one of claims 49 to 51, further including arranging a metallic layer on an exterior portion of the waveguide.

In Example 53, the method of any one of claims 49 to 52, further including arranging a dielectric material in an interior portion of the waveguide.

In Example 54, the method of any one of claims 49 to 53, further including arranging a plurality of first reflectors in the first silicon substrate; wherein at least one of the plurality of first reflectors is positioned opposite the waveguide relative to the first antenna.

In Example 55, the method of claim 54, wherein the plurality of first reflectors is a plurality of vias.

In Example 56, the method of claim 54 or 55, wherein the plurality of first reflectors is arranged to reflect a radiofrequency signal of the first antenna toward the waveguide.

In Example 57, the method of any one of claims 49 to 56, further including arranging a plurality of second reflectors in the second silicon substrate; wherein at least one of the second reflectors is positioned opposite the waveguide relative to the second antenna.

In Example 58, the method of claim 57, wherein the plurality of second reflectors is a plurality of vias.

In Example 59, the method of claim 57 or 58, further including arranging the plurality of second reflectors to reflect a radiofrequency signal of the second antenna toward the waveguide.

In Example 60, the method of any one of claims 49 to 59, wherein the first antenna and the second antenna are parallel to each other.

In Example 61, the method of any one of claims 54 to 60, further including arranging each of the plurality of first reflectors and the plurality of second reflectors along an axis perpendicular to a longitudinal axis of the waveguide.

In Example 62, the method of any one of claims 54 to 60, wherein the plurality of first reflectors includes a first subgroup of first reflectors and a second subgroup of first reflectors; wherein the first subgroup of first reflectors is arranged along a first axis; wherein the second subgroup of first reflectors is arranged along a second axis; and wherein each of the first axis and the second axis are at an angle of fewer than 90 degrees relative to a longitudinal axis of the waveguide.

In Example 63, the method of any one of claims 54 to 60, wherein the plurality of first reflectors includes a first subgroup of first reflectors, a second subgroup of first reflectors, and a third subgroup of first reflectors; wherein the first subgroup of first reflectors is arranged along a first axis perpendicular to a longitudinal axis of the waveguide; and wherein the second subgroup of first reflectors and the third subgroup of first reflectors are each arranged along axes parallel to the longitudinal axis of the waveguide.

In Example 64, the method of any one of claims 54 to 60, wherein the plurality of first reflectors includes a first subgroup of first reflectors, a second subgroup of first reflectors, and a third subgroup of first reflectors; wherein the first subgroup of first reflectors is arranged along a first axis perpendicular to a longitudinal axis of the waveguide; and wherein each of the second subgroup of first reflectors and the third subgroup of first reflectors are arranged along a curve, such that a distance between a reflector of the second subgroup of first reflectors or the third subgroup of first reflectors and a longitudinal axis of the waveguide increases as a distance between the reflector and the waveguide decreases.

In Example 65, the method of any one of claims 49 to 64, further including arranging a third silicon substrate above or below the second silicon substrate and a third magneto-dielectric material adjacent to the third silicon substrate; and wherein the waveguide has a first opening adjacent to the first magneto-dielectric material, a second opening adjacent to the second magneto-dielectric material, and a third opening adjacent to the third magneto-dielectric material.

In Example 66, the method of any one of claims 49 to 65, further including arranging one or more electrically conductive connections between the first silicon substrate and the second silicon substrate.

In Example 67, the wireless chip-to-chip device of any one of Examples 1 to 44, further comprising a heatsink, wherein the waveguide is mounted to the heatsink.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

1. A wireless chip-to-chip device, comprising:
a first substrate comprising a first antenna, configured to emit a radiofrequency signal;
a second substrate comprising a second antenna, configured to receive the radiofrequency signal; and
a waveguide, positioned between the first substrate and the second substrate.

2. (canceled)

3. The wireless chip-to-chip device of claim 1, further comprising a first gap between the first silicon substrate and the waveguide, and a second gap between the second silicone substrate and the waveguide.

4. The wireless chip-to-chip device of claim 3, further comprising a first magneto-dielectric material in the first gap; and a second magneto-dielectric material in the second gap.

5. The wireless chip-to-chip device of claim 1, wherein the first antenna and the second antenna are polarized along an axis that is perpendicular to an axis through the first silicon substrate, the waveguide, and the second silicon substrate.

6. The wireless chip-to-chip device of claim 1, wherein an exterior portion of the waveguide comprises a metallic layer.

7. The wireless chip-to-chip device of claim 1, wherein an interior portion of the waveguide comprises a dielectric material.

8. The wireless chip-to-chip device of claim 1, wherein the first silicon substrate further comprises a plurality of first reflectors; wherein at least one of the plurality of first reflectors is positioned opposite the waveguide relative to the first antenna; and wherein the plurality of first reflectors is a plurality of vias.

9. (canceled)

10. The wireless chip-to-chip device of claim 8, wherein the plurality of first reflectors is arranged to reflect a radiofrequency signal of the first antenna toward the waveguide.

11. The wireless chip-to-chip device of claim 1, wherein the second silicon substrate further comprises a plurality of second reflectors; wherein at least one of the second reflectors is positioned opposite the waveguide relative to the second antenna.

12. The wireless chip-to-chip device of claim 11, wherein the plurality of second reflectors is a plurality of vias.

13. The wireless chip-to-chip device of claim 11, wherein the plurality of second reflectors is arranged to reflect a radiofrequency signal of the second antenna toward the waveguide.

14. The wireless chip-to-chip device of claim 7, wherein each of the plurality of first reflectors and the plurality of second reflectors is arranged along an axis perpendicular to a longitudinal axis of the waveguide.

15. The wireless chip-to-chip device of claim 7, wherein the plurality of first reflectors comprises a first subgroup of first reflectors and a second subgroup of first reflectors; wherein the first subgroup of first reflectors is arranged along a first axis; wherein the second subgroup of first reflectors is arranged along a second axis; and wherein each of the first axis and the second axis are at an angle of equal to or fewer than 90 degrees relative to a longitudinal axis of the waveguide.

16. The wireless chip-to-chip device of claim 7, wherein the plurality of first reflectors comprises a first subgroup of first reflectors, a second subgroup of first reflectors, and a third subgroup of first reflectors; wherein the first subgroup of first reflectors is arranged along a first axis perpendicular to a longitudinal axis of the waveguide; and wherein the second subgroup of first reflectors and the third subgroup of first reflectors are each arranged along axes parallel to the longitudinal axis of the waveguide.

17. The wireless chip-to-chip device of claim 7, wherein the plurality of first reflectors comprises a first subgroup of first reflectors, a second subgroup of first reflectors, and a third subgroup of first reflectors; wherein the first subgroup of first reflectors is arranged along a first axis perpendicular to a longitudinal axis of the waveguide; and wherein each of the second subgroup of first reflectors and the third subgroup of first reflectors are arranged along a curve, such that a distance between a reflector of the second subgroup of first reflectors or the third subgroup of first reflectors and a longitudinal axis of the waveguide increases as a distance between the reflector and the waveguide decreases.

18. The wireless chip-to-chip device of claim 1, further comprising a third silicon substrate above or below the second silicon substrate; wherein the waveguide has a first opening adjacent to the first substrate, a second opening adjacent to the second substrate, and a third opening adjacent to the third substrate.

19. The wireless chip-to-chip device of claim 1, further comprising one or more electrically conductive connections between the first silicon substrate and the second silicon substrate.

20. The wireless chip-to-chip device of claim 1, further comprising a metal layer on the waveguide.

21. The wireless chip-to-chip device of claim 1, further comprising a groove on an exterior surface of the waveguide.

22. A multichip package comprising, a first wireless chip-to-chip device according to claim 1, and a second wireless chip-to-chip device according to claim 1.

23. (canceled)

24. (canceled)

25. (canceled)
